(19) United States
(12) Patent Application Publication
(10) Pub. No.: US 2020/0350350 A1
(43) Pub. Date: Nov. 5, 2020

(54) IMAGE SENSORS, METHODS, AND PIXELS WITH FLOATING DIFFUSION AND GATE FOR CHARGE STORAGE

(71) Applicant: Alexander Krymski, Sunny Isles Beach, FL (US)

(72) Inventor: Alexander Krymski, Sunny Isles Beach, FL (US)

(21) Appl. No.: 16/399,806

(22) Filed: Apr. 30, 2019

(51) Int. Cl. H01L 27/146; H04N 5/378; H04N 5/3745

(52) U.S. Cl. CPC H01L 27/14614; H01L 27/14643; H01L 27/14616; H04N 5/353; H04N 5/37452; H01L 27/14689; H04N 5/378

(57) ABSTRACT

A pixel includes a photodiode, a first transfer gate, a second transfer gate, and a floating diffusion. The pixel may include a storage gate, and the first transfer gate may be controllable to transfer charge from the photodiode to an area under the storage gate. The storage gate is controllable to store the charge in the area under the storage gate and to transfer the charge from the area under the storage gate. The first transfer gate may be controllable among a first biasing condition in which charge is transferable to an area under the first transfer gate, a second biasing condition in which the charge is storable in the area under the first transfer gate, and a third biasing condition in which the charge is transferable out of the area under the first transfer gate. The second transfer gate is controllable to transfer charge to the floating diffusion.

### FIELD

Embodiments of the present invention relate generally to image sensors, pixels, methods of using image sensors and pixels, and methods of manufacturing image sensors and pixels.

### BACKGROUND

Image sensors have found wide application in consumer and industrial electronics, and have enabled an explosion in the number of digital cameras and digital video devices used for work and entertainment. An image sensor typically includes a pixel array with pixels that are arranged in rows and columns. Each pixel typically includes a light sensitive element, such as a photodiode, or the like, to sample light intensity of a corresponding portion of a scene being imaged, and each pixel is typically configured to produce an analog pixel signal based on the sampled light intensity.

In some image sensors, there are different start and/or end times for the accumulation of charge in each row of pixels in the pixel array. This causes an exposure time skew, which can be observed in pictures of moving objects, and which can cause an undesirable picture distortion. This method of image sensor operation is called a “rolling shutter” operation. In some applications, however, it is preferable to expose all of the pixels of an image sensor at the same time for a same time period without the skew, and thus eliminate the distortion of moving objects. This type of image sensor operation is called a “global shutter” operation. In order to implement this kind of global shuttering, a charge storage site is typically provided in each of the pixels. After charge is integrated in the photodiodes of the pixels, it is typically transferred to the pixel storage sites simultaneously in all of the pixels of the pixel array where it can wait for readout in a row by row fashion.

### SUMMARY OF THE DISCLOSURE

Various embodiments disclosed herein provide improvements for storing and transferring charge within pixels of an image sensor, so as to avoid a loss of charge and to facilitate the transfer of charge to provide accurate reads-out from the pixels. Also, various embodiments disclosed herein allow for a reduction in parasitic capacitance in pixels of an image sensor, so as to allow for a reduction in the size of the pixels.

A pixel in accordance with an embodiment includes a photodiode, a first transfer gate, a storage gate, a second transfer gate, and a floating diffusion. The first transfer gate is controllable to transfer charge from the photodiode to an area under the storage gate. The storage gate is controllable to store the charge in the area under the storage gate and to transfer the charge from the area under the storage gate. The second transfer gate is controllable to transfer the charge from the area under the storage gate to the floating diffusion. The floating diffusion is connected to a readout circuit to allow the readout circuit to read out a voltage level of a potential at the floating diffusion.

In various embodiments, the storage gate is connected to receive a storage gate signal that controls the storage gate. In various embodiments, the storage gate is located between the first transfer gate and the second transfer gate. Also, in various embodiments, the storage gate, the first transfer gate, and the second transfer gate are polysilicon gates. In some embodiments, the readout circuit includes a source follower transistor and the floating diffusion is directly connected to a gate of the source follower transistor. In some embodiments, the pixel further includes a reset transistor that is connected between a reset voltage source and the floating diffusion and that has a gate connected to receive a reset control signal.

In various embodiments, the pixel further includes a substrate under the storage gate, the first transfer gate, and the second transfer gate. Also, in various embodiments, the pixel further includes a first implant in the substrate located between an area under the first transfer gate and the area under the storage gate, and a second implant in the substrate located between the area under the storage gate and an area under the second transfer gate. In some embodiments, the first implant and the second implant each comprise arsenic. In some embodiments, the pixel further includes a first barrier implant in the substrate under a portion of the storage gate, and a second barrier implant in the substrate under a portion of the second transfer gate. Also, in some embodiments, the first barrier implant and the second barrier implant each comprise boron.

An image sensor in accordance with an embodiment includes a pixel array having a plurality of pixels. In various embodiments, at least one pixel of the plurality of pixels includes a photodiode, a first transfer gate, a storage gate, a second transfer gate, and a floating diffusion. The first transfer gate is controllable to transfer charge from the photodiode to an area under the storage gate. The storage gate is controllable to store the charge in the area under the storage gate and to transfer the charge from the area under the storage gate. The second transfer gate is controllable to transfer the charge from the area under the storage gate to the floating diffusion. The floating diffusion is connected to a readout circuit to allow the readout circuit to read out a voltage level of a potential at the floating diffusion.

A method in an image sensor in accordance with an embodiment includes controlling a first transfer gate to transfer charge from a photodiode to an area under a storage gate, controlling the storage gate to store the charge in the area under the storage gate, controlling the storage gate and a second transfer gate to transfer the charge from the area under the storage gate to a floating diffusion, and reading out a voltage level of a potential at the floating diffusion using a readout circuit that is connected to the floating diffusion. In various embodiments, the first transfer gate is controlled by a first transfer control signal, the storage gate is controlled by a storage gate signal, and the second transfer gate is controlled by a second transfer control signal.

A pixel in accordance with another embodiment includes a photodiode, a first transfer gate, a second transfer gate, and a floating diffusion. The first transfer gate is controllable among a first biasing condition in which charge is transferable from the photodiode to an area under the first transfer gate, a second biasing condition in which the charge is storable in the area under the first transfer gate, and a third biasing condition in which the charge is transferable out of the area under the first transfer gate. The second transfer gate is controllable to transfer the charge from the area under the first transfer gate to the floating diffusion. The floating diffusion is connected to a readout circuit to allow the readout circuit to read out a voltage level of a potential at the floating diffusion.

In various embodiments, the pixel further includes a substrate under the first transfer gate and the second transfer gate, and an implant in the substrate located between the area under the first transfer gate and an area under the second transfer gate. In some embodiments, the implant located between the area under the first transfer gate and the area under the second transfer gate is an arsenic implant. In various embodiments, the pixel further includes a substrate under the first transfer gate. Also, in various embodiments, the photodiode includes an implant in the substrate and a portion of the implant for the photodiode extends under a portion of the first transfer gate.

A method in an image sensor in accordance with an embodiment includes controlling a first transfer gate to be in a first biasing condition such that charge is transferred from a photodiode into an area under the first transfer gate, controlling the first transfer gate to be in a second biasing condition such that the charge remains stored in the area under the first transfer gate, and controlling the first transfer gate to be in a third biasing condition and controlling a second transfer gate such that the charge is transferred from the area under the first transfer gate to a floating diffusion. In various embodiments, the method further includes reading out a voltage level of a potential at the floating diffusion.

In various embodiments, the first transfer gate is controlled to be in the second biasing condition by applying a voltage of a particular voltage level to the first transfer gate, and the first transfer gate is controlled to be in the first biasing condition by applying a voltage at a level higher than the particular voltage level to the first transfer gate, and the first transfer gate is controlled to be in the third biasing condition by applying a voltage at a level lower than the particular voltage level to the first transfer gate.

An image sensor in accordance with an embodiment includes a pixel array having a plurality of pixels. In various embodiments, at least one pixel of the plurality of pixels includes a photodiode, a first transfer gate, a second transfer gate, and a floating diffusion. The first transfer gate is controllable among a first biasing condition in which charge is transferable from the photodiode to an area under the first transfer gate, a second biasing condition in which the charge is storable in the area under the first transfer gate, and a third biasing condition in which the charge is transferable out of the area under the first transfer gate. The second transfer gate is controllable to transfer the charge from the area under the first transfer gate to the floating diffusion. The floating diffusion is connected to a readout circuit to allow the readout circuit to read out a voltage level of a potential at the floating diffusion.

### BRIEF DESCRIPTION OF THE DRAWINGS

FIG. 1 illustrates a pixel in accordance with an embodiment of the present invention that includes a floating diffusion and also has a storage gate for storing and transferring charge.

FIG. 2 illustrates a pixel in accordance with an embodiment of the present invention that is similar to the pixel of FIG. 1 and further includes implants in areas between gates.

FIG. 3 illustrates a pixel in accordance with an embodiment of the present invention that is similar to the pixel of FIG. 2 and further includes one or more barrier implants under at least a portion of one or more gates.

FIG. 4 illustrates a pixel in accordance with an embodiment of the present invention that includes a floating diffusion and also has a tri-state controlled transfer gate for storing and transferring charge.

FIG. 5 illustrates an image sensor in accordance with an embodiment of the present invention that can include any of the pixels of FIGS. 1, 2, 3, and 4.

FIG. 6 illustrates a method in accordance with an embodiment that can be used with any of the pixels of FIGS. 1, 2, and 3.

FIG. 7 illustrates a method in accordance with an embodiment that can be used with the pixel of FIG. 4.

### DETAILED DESCRIPTION

Various embodiments disclosed herein provide improvements for storing and transferring charge within pixels of an image sensor, so as to avoid a loss of charge and to facilitate the transfer of charge to provide accurate reads-out from the pixels. Also, various embodiments disclosed herein allow for a reduction in parasitic capacitance in pixels of an image sensor, so as to allow for a reduction in the size of the pixels.

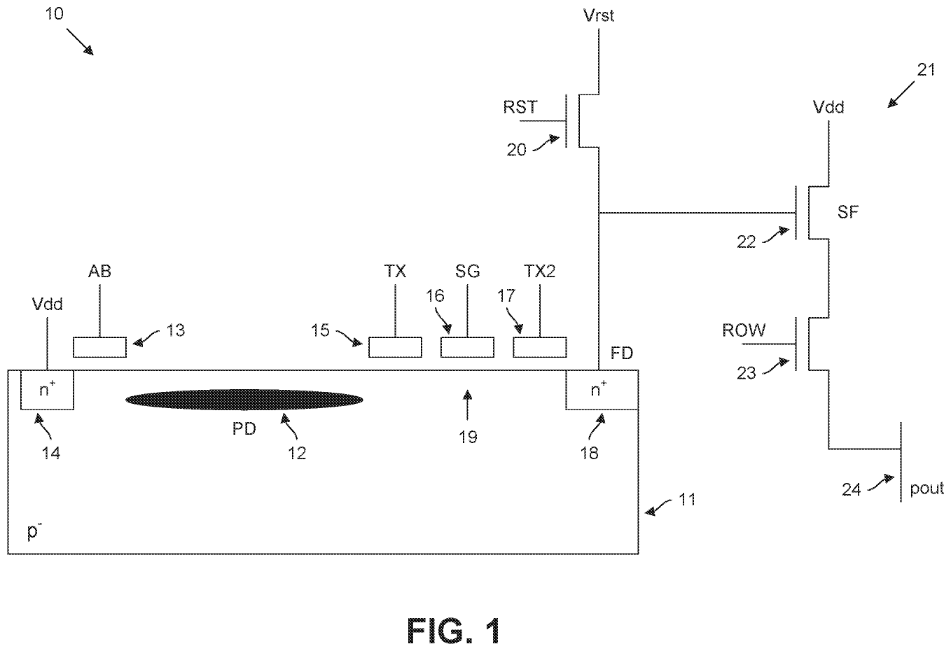

FIG. 1 illustrates a pixel 10 in accordance with an embodiment of the present invention. The pixel 10 includes a substrate 11, a photodiode (PD) 12, an anti-blooming gate 13, a drain diffusion 14, a first transfer gate 15, a storage gate 16, a second transfer gate 17, a floating diffusion (FD) 18, a reset transistor 20, and a readout circuit 21. The readout circuit 21 includes a source follower transistor (SF) 22 and a read select transistor 23. The readout circuit 21 is connected to a readout line 24 for outputting signals from the pixel 10. The reset transistor 20, the source follower transistor 22, and the read select transistor 23 may each comprise, for example, an n-channel metal oxide semiconductor field effect transistor (NMOS transistor), or the like.

In various embodiments, the substrate 11 comprises a p⁻ type substrate. The photodiode 12 is sensitive to light and can provide charge in response to light. In various embodiments, the charge is accumulated as electrons by the photodiode 12. In various embodiments, the photodiode 12 is a pinned photodiode. In various embodiments, the anti-blooming gate 13, the first transfer gate 15, the storage gate 16, and the second transfer gate 17 are polysilicon gates that are implemented in a single polysilicon level above the substrate 11. In various embodiments, there is an oxide layer (not shown) deposited on top of the substrate 11 that provides any necessary isolations of the anti-blooming gate 13, the first transfer gate 15, the storage gate 16, and the second transfer gate 17 from the substrate 11. In various embodiments, the drain diffusion 14 includes an n⁺ type implant in the substrate 11. Also, in various embodiments, the floating diffusion 18 includes an n⁺ type implant in the substrate 11. In various embodiments, the dopant for the floating diffusion 18 is an n type dopant, such as arsenic or phosphorus, and the floating diffusion 18 is an n⁺ region.

The first transfer gate 15 is connected to receive a first transfer control signal (TX), and the first transfer gate 15 is controllable by the first transfer control signal TX to transfer charge from the photodiode 12 to an area 19 under the storage gate 16. The storage gate 16 is connected to receive a storage gate signal (SG). The storage gate 16 is controllable by the storage gate signal SG to allow for charge to be stored in the area 19 under the storage gate 16 when the storage gate signal SG is HIGH, and to transfer charge out of the area 19 under the storage gate 16 when the voltage of the storage gate signal SG is lowered. In various embodiments, charge is stored and transferred as electrons. The second transfer gate 17 is connected to receive a second transfer control signal (TX2), and the second transfer gate 17 is controllable by the second transfer control signal TX2 to transfer charge from the area 19 under the storage gate 16 to the floating diffusion 18, such that charge is transferable from the area 19 under the storage gate 16 to the floating diffusion 18 by operation of the second transfer gate 17 and the storage gate 16. The floating diffusion 18 is connected to the readout circuit 21 to allow the readout circuit 21 to read out a voltage level of a potential at the floating diffusion 18.

The second transfer gate 17 is located on an opposite side of the storage gate 16 relative to the first transfer gate 15, such that the storage gate 16 is located between the first transfer gate 15 and the second transfer gate 17. The floating diffusion 18 is located on an opposite side of the second transfer gate 17 relative to the storage gate 16, such that the second transfer gate 17 is located between the storage gate 16 and the floating diffusion 18. The anti-blooming gate 13 is located on an opposite side of the photodiode 12 relative to the first transfer gate 15. The anti-blooming gate 13 is connected to receive an anti-blooming control signal (AB), and the anti-blooming gate 13 is controllable by the anti-blooming control signal AB to allow for charge to be drained from the photodiode 12 to the drain diffusion 14. The drain diffusion 14 is connected to a voltage source that supplies a voltage (Vdd).

A first terminal of the reset transistor 20 is connected to a reset voltage source that provides a reset voltage (Vrst). A gate of the reset transistor 20 is connected to receive a reset control signal (RST). A second terminal of the reset transistor 20 is connected to the floating diffusion 18 and to a gate of the source follower transistor 22. Thus, the reset transistor 20 is connected between the reset voltage source that provides the reset voltage Vrst and the floating diffusion 18. The gate of the source follower transistor 22 is connected to the floating diffusion 18 and to the second terminal of the reset transistor 20. In the embodiment shown in FIG. 1, the floating diffusion 18 is directly connected to the gate of the source follower transistor 22. A first terminal of the source follower transistor 22 is connected to a voltage source that supplies the voltage Vdd.

A second terminal of the source follower transistor 22 is connected to a first terminal of the read select transistor 23. A gate of the read select transistor 23 is connected to receive a row select signal (ROW). A second terminal of the read select transistor 23 is connected to the readout line 24 for providing a pixel output signal (pout) for the pixel 10 on the readout line 24. Thus, the read select transistor 23 is connected between the source follower transistor 22 and the readout line 24. In the embodiment shown in FIG. 1, the readout circuit 21 includes the source follower transistor 22 and the read select transistor 23 for reading out a signal based on a voltage level of a potential at the floating diffusion 18. It should be appreciated that, in various other embodiments, the readout circuit 21 may have various other circuit structures that still provide for reading out a signal based on a voltage level of a potential at the floating diffusion 18. In various embodiments, the pixel 10 is used as a global shutter pixel.

An operation of the pixel 10 in FIG. 1 during a shutter operation may proceed as follows: (i) the first transfer control signal TX is set LOW and the anti-blooming control signal AB is set HIGH to reset the photodiode 12 by causing electrons to flow out of the photodiode 12 and under the anti-blooming gate 13 to the drain diffusion 14; (ii) the anti-blooming control signal AB is set LOW and photo-charge is collected by the photodiode 12, such as by electrons being collected in a buried channel of a pinned photodiode in a case where the photodiode 12 is a pinned photodiode; (iii) at the end of the exposure to transfer charge out of the photodiode 12, the first transfer control signal TX is set HIGH and the storage gate signal SG is set HIGH, which causes charge in the form of electrons to be transferred out of the photodiode 12 and under the first transfer gate 15 to the area 19 under the storage gate 16; (iv) the first transfer control signal TX is set LOW and the electrons remain stored in the area 19 under the storage gate 16 as the second transfer control signal TX2 is held LOW; (v) the reset control signal RST is set HIGH to reset the floating diffusion 18 to a high voltage and then the reset control signal RST is set LOW, and the row select signal ROW is set HIGH to read out a potential (the reset value) of the empty floating diffusion 18 over the readout line 24 and then the row select signal ROW is set LOW; (vi) the second transfer control signal TX2 is set HIGH and the voltage applied by the storage gate signal SG to the storage gate 16 is lowered to cause the charge that was stored as electrons in the area 19 under the storage gate 16 to be transferred under the second transfer gate 17 to the floating diffusion 18; (vii) the second transfer control signal TX2 is set LOW to hold the charge at the floating diffusion 18 and the row select signal ROW is set HIGH to control the read select transistor 23 to provide output to the readout line 24 that is representative of an amount of charge stored at the floating diffusion 18.

In various embodiments, the anti-blooming gate 13 provides the exposure control. For example, in various embodiments, the exposure time is the time between the time at which the anti-blooming gate 13 is turned off by the anti-blooming control signal AB being set to LOW and the time at which the first transfer gate 15 is activated by the first transfer control signal TX being pulsed HIGH. At the end of the exposure, the photodiode charge is transferred to a channel in the area 19 under the storage gate 16. When the storage gate signal SG is HIGH, a potential well is formed in the area 19 under the storage gate 16. Applying a voltage to the storage gate 16 makes a depletion region in the area 19 under the storage gate 16 that makes the potential well in the area 19, and electrons are then attracted to that potential well and accumulate in the area 19 under the storage gate 16. This allows for storing the electrons transferred from the photodiode 12 in the area 19 under the storage gate 16. A new exposure that involves charge collection at the photodiode 12 can then start at the photodiode 12 while the charge from the previous exposure is sitting in the area 19 under the storage gate 16.

Charge stored in the area 19 under the storage gate 16 is transferred to the floating diffusion 18 when the second transfer control signal TX2 is HIGH and the storage gate signal SG is lowered in voltage. By lowering the voltage of the storage gate signal SG, the potential of the potential well in the area 19 under the storage gate 16 is lowered, which causes the electrons to flow out of the area 19 under the storage gate 16 to the floating diffusion 18. This facilitates the transfer of the electrons from the area 19 under the storage gate 16 to the floating diffusion 18. Having an improved charge transfer from the area 19 under the storage gate 16 to the floating diffusion 18 improves the accuracy of the pixel output signal (pout) read from the pixel 10.

Performing readout with the readout circuit 21 from the floating diffusion 18 rather than connecting the readout circuit 21 directly to a storage gate provides for various advantages. If readout were performed directly from a storage gate, then the storage gate would have a large parasitic capacitance because the design rules would dictate that the polysilicon gate needs to overlap the corresponding channel, so the storage gate in such a situation could not be made arbitrarily small and, thus, the conversion gain in such a situation could not be made high. In such a situation with readout directly from a storage gate, the conversion gain of a pixel may be limited to 100 microvolts per electron. That could become a serious problem in the design of small pixels, such as pixels smaller than 4 μm.

By having the readout circuit 21 connected directly to the floating diffusion 18, the reset transistor 20 and the source follower transistor 22 are connected to the floating diffusion 18 rather than directly to a storage gate. In such a situation as in the embodiment of FIG. 1, the floating diffusion 18 can be made very small, and the conversion gain can be made a few hundred microvolts per electron. Thus, various embodiments allow for having better conversion gain and smaller pixels.

In the pixel 10 of FIG. 1, the first transfer gate 15 is controllable to transfer charge from the photodiode 12 to the area 19 under the storage gate 16. The storage gate 16 is controllable to store the charge in the area 19 under the storage gate 16 and to transfer the charge from the area 19 under the storage gate 16. The second transfer gate 17 is controllable to transfer the charge from the area 19 under the storage gate 16 to the floating diffusion 18. The floating diffusion 18 is connected to the readout circuit 21 to allow the readout circuit 21 to read out a voltage level of a potential at the floating diffusion 18.

The storage gate 16 is connected to receive the storage gate signal SG that controls the storage gate 16. The storage gate 16 is located between the first transfer gate 15 and the second transfer gate 17. In various embodiments, the first transfer gate 15, the storage gate 16, and the second transfer gate 17 are polysilicon gates. The readout circuit 21 includes the source follower transistor 22. The floating diffusion 18 is directly connected to a gate of the source follower transistor 22. The reset transistor 20 is connected between a reset voltage source, which supplies the reset voltage Vrst, and the floating diffusion 18. The reset transistor 20 has a gate connected to receive the reset control signal RST.

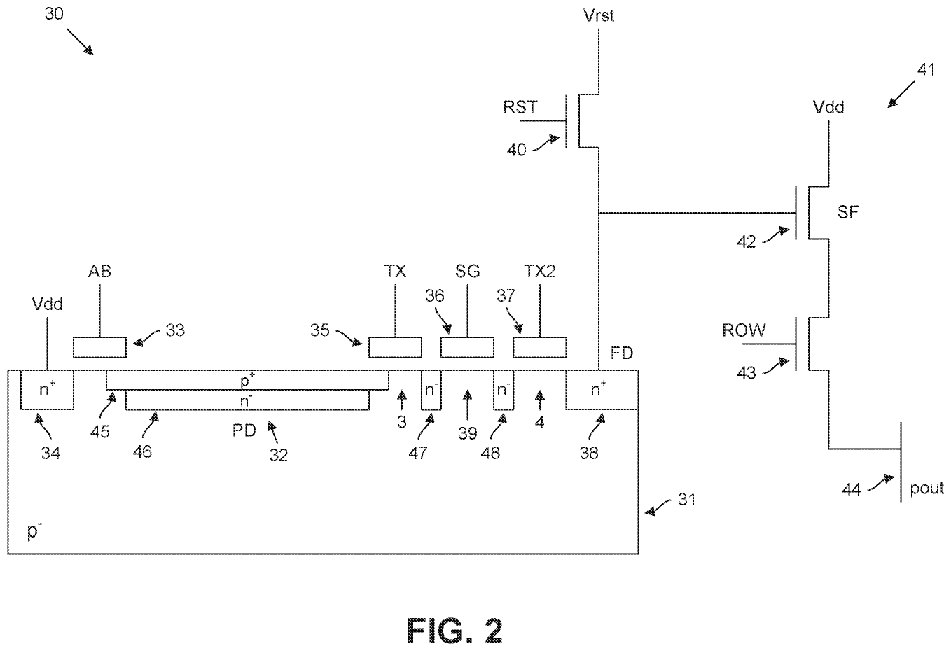

FIG. 2 illustrates a pixel 30 in accordance with an embodiment of the present invention. The pixel 30 includes a substrate 31, a photodiode (PD) 32, an anti-blooming gate 33, a drain diffusion 34, a first transfer gate 35, a storage gate 36, a second transfer gate 37, a floating diffusion (FD) 38, a reset transistor 40, and a readout circuit 41. The readout circuit 41 includes a source follower transistor (SF) 42 and a read select transistor 43. The readout circuit 41 is connected to a readout line 44 for outputting signals from the pixel 30. The reset transistor 40, the source follower transistor 42, and the read select transistor 43 may each comprise, for example, an n-channel metal oxide semiconductor field effect transistor (NMOS transistor), or the like.

In various embodiments, the substrate 31 comprises a p⁻ type substrate. The photodiode 32 is sensitive to light and can provide charge in response to light. In various embodiments, the charge is accumulated as electrons by the photodiode 32. In various embodiments, the photodiode 32 includes a region 45 of a p⁺ type doped implant in the substrate 31 and a region 46 of an n⁻ type doped implant in the substrate 31. In various embodiments, the dopant for the region 45 is a p type dopant such as Boron. In various embodiments, the dopant for the region 46 is an n type dopant, such as arsenic or phosphorus. In various embodiments, a portion of the region 45 of the photodiode 32 extends under a portion of the anti-blooming gate 33, and another portion of the region 45 of the photodiode 32 extends under a portion of the first transfer gate 35.

In various embodiments, the anti-blooming gate 33, the first transfer gate 35, the storage gate 36, and the second transfer gate 37 are polysilicon gates that are implemented in a single polysilicon level above the substrate 31. In various embodiments, there is an oxide layer (not shown) deposited on top of the substrate 31 that provides any necessary isolations of the anti-blooming gate 33, the first transfer gate 35, the storage gate 36, and the second transfer gate 37 from the substrate 31. In various embodiments, the drain diffusion 34 includes an n⁺ type implant in the substrate 31. Also, in various embodiments, the floating diffusion 38 includes an n type implant in the substrate 31. In various embodiments, the dopant for the floating diffusion 38 is an n type dopant, such as arsenic or phosphorus, and the floating diffusion 38 is an n⁺ region.

The first transfer gate 35 is connected to receive a first transfer control signal (TX), and the first transfer gate 35 is controllable by the first transfer control signal TX to transfer charge from the photodiode 32 to an area 39 under the storage gate 36. The storage gate 36 is connected to receive a storage gate signal (SG). The storage gate 36 is controllable by the storage gate signal SG to allow for charge to be stored in the area 39 under the storage gate 36 when the storage gate signal SG is HIGH, and to transfer charge out of the area 39 under the storage gate 36 when the voltage of the storage gate signal SG is lowered. In various embodiments, charge is stored and transferred as electrons. The second transfer gate 37 is connected to receive a second transfer control signal (TX2), and the second transfer gate 37 is controllable by the second transfer control signal TX2 to transfer charge from the area 39 under the storage gate 36 to the floating diffusion 38, such that charge is transferable from the area 39 under the storage gate 36 to the floating diffusion 38 by operation of the second transfer gate 37 and the storage gate 36. The floating diffusion 38 is connected to the readout circuit 41 to allow the readout circuit 41 to read out a voltage level of a potential at the floating diffusion 38.

The second transfer gate 37 is located on an opposite side of the storage gate 36 relative to the first transfer gate 35, such that the storage gate 36 is located between the first transfer gate 35 and the second transfer gate 37. The floating diffusion 38 is located on an opposite side of the second transfer gate 37 relative to the storage gate 36, such that the second transfer gate 37 is located between the storage gate 36 and the floating diffusion 38. The anti-blooming gate 33 is located on an opposite side of the photodiode 32 relative to the first transfer gate 35. The anti-blooming gate 33 is connected to receive an anti-blooming control signal (AB), and the anti-blooming gate 33 is controllable by the anti-blooming control signal AB to allow for charge to be drained from the photodiode 32 to the drain diffusion 34. The drain diffusion 34 is connected to a voltage source that supplies a voltage (Vdd).

A first terminal of the reset transistor 40 is connected to a reset voltage source that provides a reset voltage (Vrst). A gate of the reset transistor 40 is connected to receive a reset control signal (RST). A second terminal of the reset transistor 40 is connected to the floating diffusion 38 and to a gate of the source follower transistor 42. Thus, the reset transistor 40 is connected between the reset voltage source that provides the reset voltage Vrst and the floating diffusion 38. The gate of the source follower transistor 42 is connected to the floating diffusion 38 and to the second terminal of the reset transistor 40. In the embodiment shown in FIG. 2, the floating diffusion 38 is directly connected to the gate of the source follower transistor 42. A first terminal of the source follower transistor 42 is connected to a voltage source that supplies the voltage Vdd.

A second terminal of the source follower transistor 42 is connected to a first terminal of the read select transistor 43. A gate of the read select transistor 43 is connected to receive a row select signal (ROW). A second terminal of the read select transistor 43 is connected to the readout line 44 for providing a pixel output signal (pout) for the pixel 30 on the readout line 44. Thus, the read select transistor 43 is connected between the source follower transistor 42 and the readout line 44. In the embodiment shown in FIG. 2, the readout circuit 41 includes the source follower transistor 42 and the read select transistor 43 for reading out a signal based on a voltage level of a potential at the floating diffusion 38. It should be appreciated that, in various other embodiments, the readout circuit 41 may have various other circuit structures that still provide for reading out a signal based on a voltage level of a potential at the floating diffusion 38. In various embodiments, the pixel 30 is used as a global shutter pixel.

The pixel 30 further includes a first implant 47 in the substrate 31 located between an area 3 under the first transfer gate 35 and the area 39 under the storage gate 36, and also includes a second implant 48 in the substrate 31 located between the area 39 under the storage gate 36 and an area 4 under the second transfer gate 37. In various embodiments, the first implant 47 is an n-type doped implant and the second implant 48 is an n⁻ type doped implant. In various embodiments, the dopant for the first implant 47 is an n type dopant, such as arsenic or phosphorus. Also, in various embodiments, the dopant for the second implant 48 is an n type dopant, such as arsenic or phosphorus. In various embodiments, the first implant 47 is a low-dose Arsenic implant, and the second implant 48 is a low-dose Arsenic implant. The first implant 47 avoids a barrier from forming between the area 3 under the first transfer gate 35 and the area 39 under the storage gate 36 that would prevent a full charge transfer from the photodiode 32 to the area 38 under the storage gate 36. The second implant 48 avoids a barrier from forming between the area 39 under the storage gate 36 and the area 4 under the second transfer gate 37 that would prevent a full charge transfer from the area 39 under the storage gate 36 to the floating diffusion 38. Thus, in various embodiments, the first implant 47 and the second implant 48 improve charge transfer within the pixel 30.

An operation of the pixel 30 in FIG. 2 during a shutter operation may proceed as follows: (i) the first transfer control signal TX is set LOW and the anti-blooming control signal AB is set HIGH to reset the photodiode 32 by causing electrons to flow out of the photodiode 32 and under the anti-blooming gate 33 to the drain diffusion 34; (ii) the anti-blooming control signal AB is set LOW and photo-charge is collected by the photodiode 32; (iii) at the end of the exposure to transfer charge out of the photodiode 32, the first transfer control signal TX is set HIGH and the storage gate signal SG is set HIGH, which causes charge in the form of electrons to be transferred out of the photodiode 32 and under the first transfer gate 35 to the area 39 under the storage gate 36; (iv) the first transfer control signal TX is set LOW and the electrons remain stored in the area 39 under the storage gate 36 as the second transfer control signal TX2 is held LOW; (v) the reset control signal RST is set HIGH to reset the floating diffusion 38 to a high voltage and then the reset control signal RST is set LOW, and the row select signal ROW is set HIGH to read out a potential (the reset value) of the empty floating diffusion 38 over the readout line 44 and then the row select signal ROW is set LOW; (vi) the second transfer control signal TX2 is set HIGH and the voltage applied by the storage gate signal SG to the storage gate 36 is lowered to cause the charge that was stored as electrons in the area 39 under the storage gate 36 to be transferred under the second transfer gate 37 to the floating diffusion 38; (vii) the second transfer control signal TX2 is set LOW to hold the charge at the floating diffusion 38 and the row select signal ROW is set HIGH to control the read select transistor 43 to provide output to the readout line 44 that is representative of an amount of charge stored at the floating diffusion 38.

In various embodiments, the anti-blooming gate 33 provides the exposure control. For example, in various embodiments, the exposure time is the time between the time at which the anti-blooming gate 33 is turned off by the anti-blooming control signal AB being set to LOW and the time at which the first transfer gate 35 is activated by the first transfer control signal TX being pulsed HIGH. At the end of the exposure, the photodiode charge is transferred to a channel in the area 39 under the storage gate 36. When the storage gate signal SG is HIGH, a potential well is formed in the area 39 under the storage gate 36. Applying a voltage to the storage gate 36 makes a depletion region in the area 39 under the storage gate 36 that makes the potential well in the area 39, and electrons are then attracted to that potential well and accumulate in the area 39 under the storage gate 36. This allows for storing the electrons transferred from the photodiode 32 in the area 39 under the storage gate 36. A new exposure that involves charge collection at the photodiode 32 can then start at the photodiode 32 while the charge from the previous exposure is sitting in the area 39 under the storage gate 36.

Charge stored in the area 39 under the storage gate 36 is transferred to the floating diffusion 38 when the second transfer control signal TX2 is HIGH and the storage gate signal SG is lowered in voltage. By lowering the voltage of the storage gate signal SG, the potential of the potential well in the area 39 under the storage gate 36 is lowered, which causes the electrons to flow out of the area 39 under the storage gate 36 to the floating diffusion 38. This facilitates the transfer of the electrons from the area 39 under the storage gate 36 to the floating diffusion 38. Having an improved charge transfer from the area 39 under the storage gate 36 to the floating diffusion 38 improves the accuracy of the pixel output signal (pout) read from the pixel 30.

Performing readout with the readout circuit 41 from the floating diffusion 38 rather than connecting the readout circuit 41 directly to a storage gate provides for various advantages. If readout were performed directly from a storage gate, then the storage gate would have a large parasitic capacitance because the design rules would dictate that the polysilicon gate needs to overlap the corresponding channel, so the storage gate in such a situation could not be made arbitrarily small and, thus, the conversion gain in such a situation could not be made high. In such a situation with readout directly from a storage gate, the conversion gain of a pixel may be limited to 300 microvolts per electron. That could become a serious problem in the design of small pixels, such as pixels smaller than 4 μm.

By having the readout circuit 41 connected directly to the floating diffusion 38, the reset transistor 40 and the source follower transistor 42 are connected to the floating diffusion 38 rather than directly to a storage gate. In such a situation as in the embodiment of FIG. 2, the floating diffusion 38 can be made very small, and the conversion gain can be made a few hundred microvolts per electron. Thus, various embodiments allow for having better conversion gain and smaller pixels.

The first implant 47 facilitates the transfer of charge when the charge is being transferred from the photodiode 32 to the area 39 under the storage gate 36. The second implant 48 facilitates the transfer of charge when the charge is being transferred from the area 39 under the storage gate 36 to the floating diffusion 38. Thus, in various embodiments, the first implant 47 and the second implant 48 improve charge transfer within the pixel 30 so as to improve the accuracy of the pixel output signal (pout) read from the pixel 30.

In the pixel 30 of FIG. 2, the first transfer gate 35 is controllable to transfer charge from the photodiode 32 to the area 39 under the storage gate 36. The storage gate 36 is controllable to store the charge in the area 39 under the storage gate 36 and to transfer the charge from the area 39 under the storage gate 36. The second transfer gate 37 is controllable to transfer the charge from the area 39 under the storage gate 36 to the floating diffusion 38. The floating diffusion 38 is connected to the readout circuit 41 to allow the readout circuit 41 to read out a voltage level of a potential at the floating diffusion 38.

The storage gate 36 is connected to receive the storage gate signal SG that controls the storage gate 36. The storage gate 36 is located between the first transfer gate 35 and the second transfer gate 37. In various embodiments, the first transfer gate 35, the storage gate 36, and the second transfer gate 37 are polysilicon gates. The readout circuit 41 includes the source follower transistor 42. The floating diffusion 38 is directly connected to a gate of the source follower transistor 42. The reset transistor 40 is connected between a reset voltage source, which supplies the reset voltage Vrst, and the floating diffusion 38. The reset transistor 40 has a gate connected to receive the reset control signal RST. The pixel 30 includes the substrate 31 under the first transfer gate 35, the storage gate 36, and the second transfer gate 37. The pixel 30 includes the first implant 47 in the substrate 31 located between the area 3 under the first transfer gate 35 and the area 39 under the storage gate 36, and the pixel 30 also includes the second implant 48 in the substrate 31 located between the area 39 under the storage gate 36 and the area 4 under the second transfer gate 37. In some embodiments, the first implant 47 and the second implant 48 are each low-dose arsenic implants.

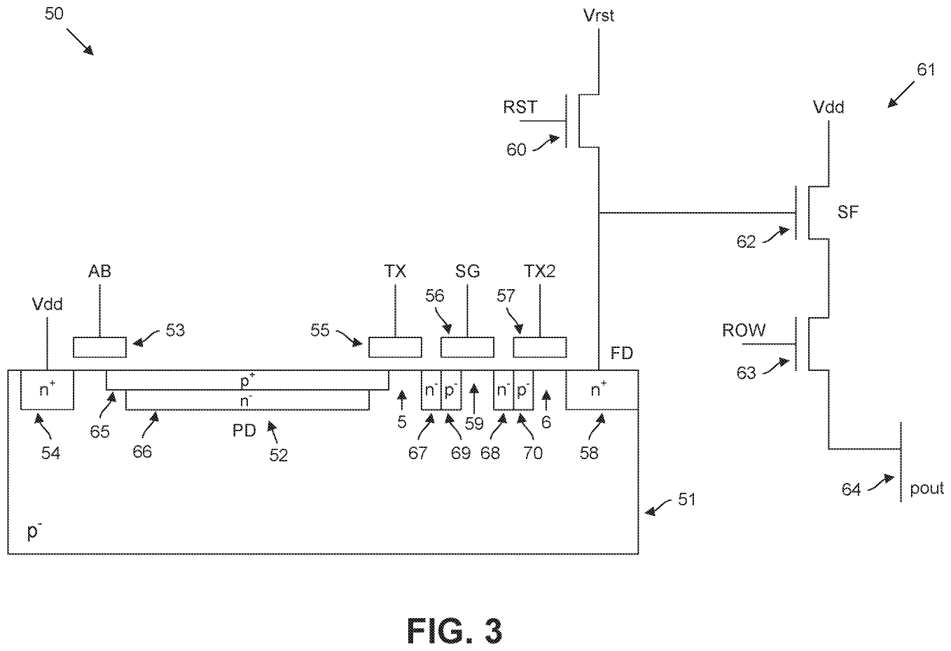

FIG. 3 illustrates a pixel 50 in accordance with an embodiment of the present invention. The pixel 50 includes a substrate 51, a photodiode (PD) 52, an anti-blooming gate 53, a drain diffusion 54, a first transfer gate 55, a storage gate 56, a second transfer gate 57, a floating diffusion (FD) 58, a reset transistor 60, and a readout circuit 61. The readout circuit 61 includes a source follower transistor (SF) 62 and a read select transistor 63. The readout circuit 61 is connected to a readout line 64 for outputting signals from the pixel 50. The reset transistor 60, the source follower transistor 62, and the read select transistor 63 may each comprise, for example, an n-channel metal oxide semiconductor field effect transistor (NMOS transistor), or the like.

In various embodiments, the substrate 51 comprises a p⁻ type substrate. The photodiode 52 is sensitive to light and can provide charge in response to light. In various embodiments, the charge is accumulated as electrons by the photodiode 52. In various embodiments, the photodiode 52 includes a region 65 of a p⁺ type doped implant in the substrate 51 and a region 66 of an n⁻ type doped implant in the substrate 51. In various embodiments, the dopant for the region 65 is a p type dopant such as Boron. In various embodiments, the dopant for the region 66 is an n type dopant, such as arsenic or phosphorus. In various embodiments, a portion of the region 65 of the photodiode 52 extends under a portion of the anti-blooming gate 53, and another portion of the region 65 of the photodiode 52 extends under a portion of the first transfer gate 55.

In various embodiments, the anti-blooming gate 53, the first transfer gate 55, the storage gate 56, and the second transfer gate 57 are polysilicon gates that are implemented in a single polysilicon level above the substrate 51. In various embodiments, there is an oxide layer (not shown) deposited on top of the substrate 51 that provides any necessary isolations of the anti-blooming gate 53, the first transfer gate 55, the storage gate 56, and the second transfer gate 57 from the substrate 51. In various embodiments, the drain diffusion 54 includes an n⁺ type implant in the substrate 51. Also, in various embodiments, the floating diffusion 58 includes an n⁺ type implant in the substrate 51. In various embodiments, the dopant for the floating diffusion 58 is an n type dopant, such as arsenic or phosphorus, and the floating diffusion 58 is an n⁺ region.

The first transfer gate 55 is connected to receive a first transfer control signal (TX), and the first transfer gate 55 is controllable by the first transfer control signal TX to transfer charge from the photodiode 52 to an area 59 under the storage gate 56. The storage gate 56 is connected to receive a storage gate signal (SG). The storage gate 56 is controllable by the storage gate signal SG to allow for charge to be stored in the area 59 under the storage gate 56 when the storage gate signal SG is HIGH, and to transfer charge out of the area 59 under the storage gate 56 when the voltage of the storage gate signal SG is lowered. In various embodiments, charge is stored and transferred as electrons. The second transfer gate 57 is connected to receive a second transfer control signal (TX2), and the second transfer gate 57 is controllable by the second transfer control signal TX2 to transfer charge from the area 59 under the storage gate 56 to the floating diffusion 58, such that charge is transferable from the area 59 under the storage gate 56 to the floating diffusion 58 by operation of the second transfer gate 57 and the storage gate 56. The floating diffusion 58 is connected to the readout circuit 61 to allow the readout circuit 61 to read out a voltage level of a potential at the floating diffusion 58.

The second transfer gate 57 is located on an opposite side of the storage gate 56 relative to the first transfer gate 55, such that the storage gate 56 is located between the first transfer gate 55 and the second transfer gate 57. The floating diffusion 58 is located on an opposite side of the second transfer gate 57 relative to the storage gate 56, such that the second transfer gate 57 is located between the storage gate 56 and the floating diffusion 58. The anti-blooming gate 53 is located on an opposite side of the photodiode 52 relative to the first transfer gate 55. The anti-blooming gate 53 is connected to receive an anti-blooming control signal (AB), and the anti-blooming gate 53 is controllable by the anti-blooming control signal AB to allow for charge to be drained from the photodiode 52 to the drain diffusion 54. The drain diffusion 54 is connected to a voltage source that supplies a voltage (Vdd).

A first terminal of the reset transistor 60 is connected to a reset voltage source that provides a reset voltage (Vrst). A gate of the reset transistor 60 is connected to receive a reset control signal (RST). A second terminal of the reset transistor 60 is connected to the floating diffusion 58 and to a gate of the source follower transistor 62. Thus, the reset transistor 60 is connected between the reset voltage source that provides the reset voltage Vrst and the floating diffusion 58. The gate of the source follower transistor 62 is connected to the floating diffusion 58 and to the second terminal of the reset transistor 60. In the embodiment shown in FIG. 3, the floating diffusion 58 is directly connected to the gate of the source follower transistor 62. A first terminal of the source follower transistor 62 is connected to a voltage source that supplies the voltage Vdd.

A second terminal of the source follower transistor 62 is connected to a first terminal of the read select transistor 63. A gate of the read select transistor 63 is connected to receive a row select signal (ROW). A second terminal of the read select transistor 63 is connected to the readout line 64 for providing a pixel output signal (pout) for the pixel 50 on the readout line 64. Thus, the read select transistor 63 is connected between the source follower transistor 62 and the readout line 64. In the embodiment shown in FIG. 3, the readout circuit 61 includes the source follower transistor 62 and the read select transistor 63 for reading out a signal based on a voltage level of a potential at the floating diffusion 58. It should be appreciated that, in various other embodiments, the readout circuit 61 may have various other circuit structures that still provide for reading out a signal based on a voltage level of a potential at the floating diffusion 58. In various embodiments, the pixel 50 is used as a global shutter pixel.

The pixel 50 further includes a first implant 67 in the substrate 51 located between an area 5 under the first transfer gate 55 and the area 59 under the storage gate 56, and also includes a second implant 68 in the substrate 51 located between the area 59 under the storage gate 56 and an area 6 under the second transfer gate 57. In various embodiments, the first implant 67 is an n-type doped implant and the second implant 68 is an n⁻ type doped implant. In various embodiments, the dopant for the first implant 67 is an n type dopant, such as arsenic or phosphorus. Also, in various embodiments, the dopant for the second implant 68 is an n type dopant, such as arsenic or phosphorus. In various embodiments, the first implant 67 is a low-dose Arsenic implant, and the second implant 68 is a low-dose Arsenic implant. The first implant 67 avoids a barrier from forming between the area 5 under the first transfer gate 55 and the area 59 under the storage gate 56 that would prevent a full charge transfer from the photodiode 52 to the area 58 under the storage gate 56. The second implant 68 avoids a barrier from forming between the area 59 under the storage gate 56 and the area 6 under the second transfer gate 57 that would prevent a full charge transfer from the area 59 under the storage gate 56 to the floating diffusion 58. Thus, in various embodiments, the first implant 67 and the second implant 68 improve charge transfer within the pixel 50.

The pixel 50 further includes a first barrier implant 69 in the substrate 51 under a portion of the storage gate 56, and the pixel 50 also includes a second barrier implant 70 in the substrate 51 under a portion of the second transfer gate 57. In various embodiments, the first barrier implant 69 is located directly next to the first implant 67 and under a left side of the storage gate 56. In various embodiments, the second barrier implant 70 is located directly next to the second implant 68 and under a left side of the second transfer gate 57. In various embodiments, the first barrier implant 69 is a p⁻ type implant in the substrate 51. In various embodiments, the second barrier implant 70 is a p⁻ type implant in the substrate 51. In various embodiments, the dopant for the first barrier implant 69 is an p type dopant, such as boron. In various embodiments, the dopant for the second barrier implant 70 is an p type dopant, such as boron. In various embodiments, the first barrier implant 69 creates a barrier to prevent charge from being spilled back out of the area 59 under the storage gate 56 toward the area 5 under the first transfer gate 55 to the photodiode 52 when the storage gate signal SG provided to the storage gate 56 goes LOW. In various embodiments, the second barrier implant 70 creates a barrier to prevent charge from being spilled back away from the floating diffusion 58 toward the area 59 under the storage gate 56 when the second transfer control signal TX2 goes LOW.

An operation of the pixel 50 in FIG. 3 during a shutter operation may proceed as follows: (i) the first transfer control signal TX is set LOW and the anti-blooming control signal AB is set HIGH to reset the photodiode 52 by causing electrons to flow out of the photodiode 52 and under the anti-blooming gate 53 to the drain diffusion 54; (ii) the anti-blooming control signal AB is set LOW and photo-charge is collected by the photodiode 52; (iii) at the end of the exposure to transfer charge out of the photodiode 52, the first transfer control signal TX is set HIGH and the storage gate signal SG is set HIGH, which causes charge in the form of electrons to be transferred out of the photodiode 52 and under the first transfer gate 55 to the area 59 under the storage gate 56; (iv) the first transfer control signal TX is set LOW and the electrons remain stored in the area 59 under the storage gate 56 as the second transfer control signal TX2 is held LOW; (v) the reset control signal RST is set HIGH to reset the floating diffusion 58 to a high voltage and then the reset control signal RST is set LOW, and the row select signal ROW is set HIGH to read out a potential (the reset value) of the empty floating diffusion 58 over the readout line 64 and then the row select signal ROW is set LOW; (vi) the second transfer control signal TX2 is set HIGH and the voltage applied by the storage gate signal SG to the storage gate 56 is lowered to cause the charge that was stored as electrons in the area 59 under the storage gate 56 to be transferred under the second transfer gate 57 to the floating diffusion 58; (vii) the second transfer control signal TX2 is set LOW to hold the charge at the floating diffusion 58 and the row select signal ROW is set HIGH to control the read select transistor 63 to provide output to the readout line 64 that is representative of an amount of charge stored at the floating diffusion 58.

In various embodiments, the anti-blooming gate 53 provides the exposure control. For example, in various embodiments, the exposure time is the time between the time at which the anti-blooming gate 53 is turned off by the anti-blooming control signal AB being set to LOW and the time at which the first transfer gate 55 is activated by the first transfer control signal TX being pulsed HIGH. At the end of the exposure, the photodiode charge is transferred to a channel in the area 59 under the storage gate 56. When the storage gate signal SG is HIGH, a potential well is formed in the area 59 under the storage gate 56. Applying a voltage to the storage gate 56 makes a depletion region in the area 59 under the storage gate 56 that makes the potential well in the area 59, and electrons are then attracted to that potential well and accumulate in the area 59 under the storage gate 56. This allows for storing the electrons transferred from the photodiode 52 in the area 59 under the storage gate 56. A new exposure that involves charge collection at the photodiode 52 can then start at the photodiode 52 while the charge from the previous exposure is sitting in the area 59 under the storage gate 56.

Charge stored in the area 59 under the storage gate 56 is transferred to the floating diffusion 58 when the second transfer control signal TX2 is HIGH and the storage gate signal SG is lowered in voltage. By lowering the voltage of the storage gate signal SG, the potential of the potential well in the area 59 under the storage gate 56 is lowered, which causes the electrons to flow out of the area 59 under the storage gate 56 to the floating diffusion 58. This facilitates the transfer of the electrons from the area 59 under the storage gate 56 to the floating diffusion 58. Having an improved charge transfer from the area 59 under the storage gate 56 to the floating diffusion 58 improves the accuracy of the pixel output signal (pout) read from the pixel 50.

Performing readout with the readout circuit 61 from the floating diffusion 58 rather than connecting the readout circuit 61 directly to a storage gate provides for various advantages. If readout were performed directly from a storage gate, then the storage gate would have a large parasitic capacitance because the design rules would dictate that the polysilicon gate needs to overlap the corresponding channel, so the storage gate in such a situation could not be made arbitrarily small and, thus, the conversion gain in such a situation could not be made high. In such a situation with readout directly from a storage gate, the conversion gain of a pixel may be limited to 500 microvolts per electron. That could become a serious problem in the design of small pixels, such as pixels smaller than 4 μm.

By having the readout circuit 61 connected directly to the floating diffusion 58, the reset transistor 60 and the source follower transistor 62 are connected to the floating diffusion 58 rather than directly to a storage gate. In such a situation as in the embodiment of FIG. 3, the floating diffusion 58 can be made very small, and the conversion gain can be made a few hundred microvolts per electron. Thus, various embodiments allow for having better conversion gain and smaller pixels.

The first implant 67 facilitates the transfer of charge when the charge is being transferred from the photodiode 52 to the area 59 under the storage gate 56. The second implant 68 facilitates the transfer of charge when the charge is being transferred from the area 59 under the storage gate 56 to the floating diffusion 58. Thus, in various embodiments, the first implant 67 and the second implant 68 improve charge transfer within the pixel 50 so as to improve the accuracy of the pixel output signal (pout) read from the pixel 50. The first barrier implant 69 prevents charge from being spilled back toward the photodiode 52 when the storage gate signal SG goes LOW. The second barrier implant 70 prevents charge from being spilled back toward the area 59 under the storage gate 56 when the second transfer control signal TX2 goes LOW. Thus, in various embodiments, the first barrier implant 69 and the second barrier implant 70 improve charge transfer within the pixel 50 so as to improve the accuracy of the pixel output signal (pout) read from the pixel 50.

In the pixel 50 of FIG. 3, the first transfer gate 55 is controllable to transfer charge from the photodiode 52 to the area 59 under the storage gate 56. The storage gate 56 is controllable to store the charge in the area 59 under the storage gate 56 and to transfer the charge from the area 59 under the storage gate 56. The second transfer gate 57 is controllable to transfer the charge from the area 59 under the storage gate 56 to the floating diffusion 58. The floating diffusion 58 is connected to the readout circuit 61 to allow the readout circuit 61 to read out a voltage level of a potential at the floating diffusion 58.

The storage gate 56 is connected to receive the storage gate signal SG that controls the storage gate 56. The storage gate 56 is located between the first transfer gate 55 and the second transfer gate 57. In various embodiments, the first transfer gate 55, the storage gate 56, and the second transfer gate 57 are polysilicon gates. The readout circuit 61 includes the source follower transistor 62. The floating diffusion 58 is directly connected to a gate of the source follower transistor 62. The reset transistor 60 is connected between a reset voltage source, which supplies the reset voltage Vrst, and the floating diffusion 58. The reset transistor 60 has a gate connected to receive the reset control signal RST.

The pixel 50 includes the substrate 51 under the first transfer gate 55, the storage gate 56, and the second transfer gate 57. The pixel 50 includes the first implant 67 in the substrate 51 located between the area 5 under the first transfer gate 55 and the area 59 under the storage gate 56, and the pixel 50 also includes the second implant 68 in the substrate 51 located between the area 59 under the storage gate 56 and the area 6 under the second transfer gate 57. In some embodiments, the first implant 67 and the second implant 68 are each low-dose arsenic implants. The pixel 50 further includes the first barrier implant 69 in the substrate 51 under a portion of the storage gate 56, and the pixel 50 also includes the second barrier implant 70 in the substrate 51 under a portion of the second transfer gate 57. In some embodiments, the first barrier implant 69 and the second barrier implant 70 are each boron implants.

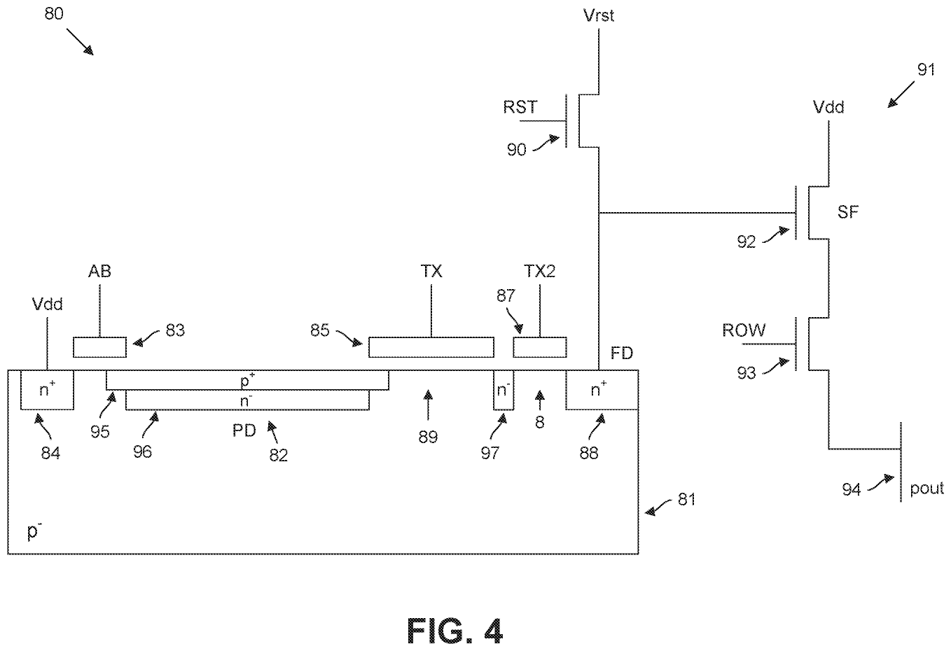

FIG. 4 illustrates a pixel 80 in accordance with an embodiment of the present invention. The pixel 80 includes a substrate 81, a photodiode (PD) 82, an anti-blooming gate 83, a drain diffusion 84, a first transfer gate 85, a second transfer gate 87, a floating diffusion (FD) 88, a reset transistor 90, and a readout circuit 91. The readout circuit 91 includes a source follower transistor (SF) 92 and a read select transistor 93. The readout circuit 91 is connected to a readout line 94 for outputting signals from the pixel 80. The reset transistor 90, the source follower transistor 92, and the read select transistor 93 may each comprise, for example, an n-channel metal oxide semiconductor field effect transistor (NMOS transistor), or the like.

In various embodiments, the substrate 81 comprises a p⁻ type substrate. The photodiode 82 is sensitive to light and can provide charge in response to light. In various embodiments, the charge is accumulated as electrons by the photodiode 82. In various embodiments, the photodiode 82 includes a region 95 of a p⁺ type doped implant in the substrate 81 and a region 96 of an n⁻ type doped implant in the substrate 81. In various embodiments, the dopant for the region 95 is a p type dopant such as Boron. In various embodiments, the dopant for the region 96 is an n type dopant, such as arsenic or phosphorus. In various embodiments, a portion of the region 95 of the photodiode 82 extends under a portion of the anti-blooming gate 83, and another portion of the region 95 of the photodiode 82 extends under a portion of the first transfer gate 85.

In various embodiments, the anti-blooming gate 83, the first transfer gate 85, and the second transfer gate 87 are polysilicon gates that are implemented in a single polysilicon level above the substrate 81. In various embodiments, there is an oxide layer (not shown) deposited on top of the substrate 81 that provides any necessary isolations of the anti-blooming gate 83, the first transfer gate 85, and the second transfer gate 87 from the substrate 81. In various embodiments, the drain diffusion 84 includes an n⁺ type implant in the substrate 81. Also, in various embodiments, the floating diffusion 88 includes an n⁺ type implant in the substrate 81. In various embodiments, the dopant for the floating diffusion 88 is an n type dopant, such as arsenic or phosphorus, and the floating diffusion 88 is an n⁺ region.

The first transfer gate 85 is connected to receive a first transfer control signal (TX). The first transfer gate 85 is controllable among at least three biasing conditions, including a first biasing condition that is a high biasing condition in which charge is transferable from the photodiode 82 to a potential well in the area 89 under the first transfer gate 85, a second biasing condition that is an intermediate biasing condition in which the charge is stored in the potential well in the area 89 under the first transfer gate 85, and a third biasing condition that is a low biasing condition in which the charge is transferable out of the potential well in the area 89 under the first transfer gate 85. In various embodiments, the charge is stored and transferred as electrons.

In various embodiments, the first transfer gate 85 is controllable to be in the second biasing condition when a voltage of a particular voltage level is applied to the first transfer gate 85 by the first transfer control signal TX, and the first transfer gate 85 is controllable to be in the first biasing condition when a voltage at a level higher than the particular voltage level is applied to the first transfer gate 85 by the first transfer control signal TX, and the first transfer gate 85 is controllable to be in the third biasing condition when a voltage at a level lower than the particular voltage level is applied to the first transfer gate 85 by the first transfer control signal TX. In some embodiments, the first transfer gate 85 is in the first biasing condition if a voltage of 3.3 V or higher is applied to the first transfer gate 85 by the first transfer control signal TX, the first transfer gate 85 is in the second biasing condition if a voltage of 1 V is applied to the first transfer gate 85 by the first transfer control signal TX, and the first transfer gate 85 is in the third biasing condition if a voltage of 0 V or lower is applied to the first transfer gate 85 by the first transfer control signal TX. Of course, those voltage values are merely provided as examples, and in various other embodiments, other suitable voltage levels can be used to control the first transfer gate 85.

The second transfer gate 87 is connected to receive a second transfer control signal (TX2), and the second transfer gate 87 is controllable by the second transfer control signal TX2 to transfer charge from the area 89 under the first transfer gate 85 to the floating diffusion 88, such that charge is transferable from the area 89 under the first transfer gate 85 to the floating diffusion 88 by operation of the second transfer gate 87 and the first transfer gate 85. The floating diffusion 88 is connected to the readout circuit 91 to allow the readout circuit 91 to read out a voltage level of a potential at the floating diffusion 88.

The second transfer gate 87 is located on an opposite side of the first transfer gate 85 relative to the photodiode 82. The floating diffusion 88 is located on an opposite side of the second transfer gate 87 relative to the first transfer gate 85, such that the second transfer gate 87 is located between the first transfer gate 85 and the floating diffusion 88. The anti-blooming gate 83 is located on an opposite side of the photodiode 82 relative to the first transfer gate 85. The anti-blooming gate 83 is connected to receive an anti-blooming control signal (AB), and the anti-blooming gate 83 is controllable by the anti-blooming control signal AB to allow for charge to be drained from the photodiode 82 to the drain diffusion 84. The drain diffusion 84 is connected to a voltage source that supplies a voltage (Vdd).

A first terminal of the reset transistor 90 is connected to a reset voltage source that provides a reset voltage (Vrst). A gate of the reset transistor 90 is connected to receive a reset control signal (RST). A second terminal of the reset transistor 90 is connected to the floating diffusion 88 and to a gate of the source follower transistor 92. Thus, the reset transistor 90 is connected between the reset voltage source that provides the reset voltage Vrst and the floating diffusion 88. The gate of the source follower transistor 92 is connected to the floating diffusion 88 and to the second terminal of the reset transistor 90. In the embodiment shown in FIG. 4, the floating diffusion 88 is directly connected to the gate of the source follower transistor 92. A first terminal of the source follower transistor 92 is connected to a voltage source that supplies the voltage Vdd.

A second terminal of the source follower transistor 92 is connected to a first terminal of the read select transistor 93. A gate of the read select transistor 93 is connected to receive a row select signal (ROW). A second terminal of the read select transistor 93 is connected to the readout line 94 for providing a pixel output signal (pout) for the pixel 80 on the readout line 94. Thus, the read select transistor 93 is connected between the source follower transistor 92 and the readout line 94. In the embodiment shown in FIG. 4, the readout circuit 91 includes the source follower transistor 92 and the read select transistor 93 for reading out a signal based on a voltage level of a potential at the floating diffusion 88. It should be appreciated that, in various other embodiments, the readout circuit 91 may have various other circuit structures that still provide for reading out a signal based on a voltage level of a potential at the floating diffusion 88. In various embodiments, the pixel 80 is used as a global shutter pixel.

The pixel 80 further includes an implant 97 in the substrate 81 located between the area 89 under the first transfer gate 85 and an area 8 under the second transfer gate 87. In various embodiments, the implant 97 is an n⁻ type doped implant. In various embodiments, the dopant for the implant 97 is an n type dopant, such as arsenic or phosphorus. In various embodiments, the implant 97 includes a bridge arsenic-doped area. In various embodiments, the implant 97 is a low-dose Arsenic implant. The implant 97 avoids a barrier from forming between the area 89 under the first transfer gate 85 and the area 8 under the second transfer gate 87 that would prevent a full charge transfer from the area 89 under the first transfer gate 85 to the floating diffusion 88. Thus, in various embodiments, the implant 97 improves charge transfer within the pixel 80.

An operation of the pixel 80 in FIG. 4 during a shutter operation may proceed as follows: (i) the first transfer control signal TX is set to the low biasing condition and the anti-blooming control signal AB is set HIGH to reset the photodiode 82 by causing electrons to flow out of the photodiode 82 and under the anti-blooming gate 83 to the drain diffusion 84; (ii) the anti-blooming control signal AB is set LOW and photo-charge is collected by the photodiode 82 (iii) at the end of the exposure to transfer charge out of the photodiode 82, the first transfer control signal TX is set to the high biasing condition, which causes charge in the form of electrons to be transferred out of the photodiode 82 to the area 89 under the first transfer gate 85; (iv) the first transfer control signal TX is set to the intermediate biasing condition and the electrons remain stored in the area 89 under the first transfer gate 85 as the second transfer control signal TX2 is held LOW; (v) the reset control signal RST is set HIGH to reset the floating diffusion 88 to a high voltage and then the reset control signal RST is set LOW, and the row select signal ROW is set HIGH to read out a potential (the reset value) of the empty floating diffusion 88 over the readout line 94 and then the row select signal ROW is set LOW; (vi) the second transfer control signal TX2 is set HIGH and the voltage applied by the first transfer control signal TX to the first transfer gate 85 is set to the low biasing condition to cause the charge that was stored as electrons in the area 89 under the first transfer gate 85 to be transferred under the second transfer gate 87 to the floating diffusion 88; (vii) the second transfer control signal TX2 is set LOW to hold the charge at the floating diffusion 88 and the row select signal ROW is set HIGH to control the read select transistor 93 to provide output to the readout line 94 that is representative of an amount of charge stored at the floating diffusion 88.

In various embodiments, the anti-blooming gate 83 provides the exposure control. For example, in various embodiments, the exposure time is the time between the time at which the anti-blooming gate 83 is turned off by the anti-blooming control signal AB being set to LOW and the time at which the first transfer gate 85 is activated by the first transfer control signal TX being set to the high biasing condition. At the end of the exposure, the photodiode charge is transferred to a channel in the area 89 under the first transfer gate 85. When the first transfer control signal TX is set to the high biasing condition, a potential well is formed in the area 89 under the first transfer gate 85. Applying a voltage to the first transfer gate 85 makes a depletion region in the area 89 under the first transfer gate 85 that makes the potential well in the area 89, and electrons are then attracted to that potential well and accumulate in the area 89 under the first transfer gate 85. This allows for transferring electrons to and storing the electrons in the area 89 under the first transfer gate 85. A new exposure that involves charge collection at the photodiode 82 can then start at the photodiode 82 while the charge from the previous exposure is sitting in the area 89 under the first transfer gate 85.

Charge stored in the area 89 under the first transfer gate 85 is transferred to the floating diffusion 88 when the second transfer control signal TX2 is HIGH and the first transfer control signal TX is set to the low biasing condition. By lowering the voltage of the first transfer control signal TX, the potential of the potential well in the area 89 under the first transfer gate 85 is lowered, which causes the electrons to flow out of the area 89 under the first transfer gate 85 to the floating diffusion 88. This facilitates the transfer of the electrons from the area 89 under the first transfer gate 85 to the floating diffusion 88. Having an improved charge transfer from the area 89 under the first transfer gate 85 to the floating diffusion 88 improves the accuracy of the pixel output signal (pout) read from the pixel 80.

The implant 97 facilitates the transfer of charge when the charge is being transferred from the area 89 under the first transfer gate 85 to the floating diffusion 88 through the area 8 under the second transfer gate 87. Thus, in various embodiments, the implant 97 improves charge transfer within the pixel 80 so as to improve the accuracy of the pixel output signal (pout) read from the pixel 80.

In the pixel 80 of FIG. 4, the first transfer gate 85 is controllable among the first biasing condition in which charge is transferable from the photodiode 82 to the area 89 under the first transfer gate 85, the second biasing condition in which the charge is storable in the area 89 under the first transfer gate 85, and the third biasing condition in which the charge is transferable out of the area 89 under the first transfer gate 85. The first transfer gate 85, therefore, has a tri-state control. The second transfer gate 87 is controllable to transfer the charge from the area 89 under the first transfer gate 85 to the floating diffusion 88. The floating diffusion 88 is connected to the readout circuit 91 to allow the readout circuit 91 to read out a voltage level of a potential at the floating diffusion 88.

The pixel 80 includes the substrate 81 under the first transfer gate 85 and the second transfer gate 87, and the pixel 80 also includes the implant 97 in the substrate 81 located between the area 89 under the first transfer gate 85 and the area 8 under the second transfer gate 87. In some embodiments, the implant 97 located between the area 89 under the first transfer gate 85 and the area 8 under the second transfer gate 87 is an arsenic implant. Also, in various embodiments, the photodiode 82 includes an implant, such as the p⁺ type doped implant for the region 95 in the substrate 81, and a portion of the implant for the photodiode 82 extends under a portion of the first transfer gate 85. In various embodiments, the pixel 80 of FIG. 4 presents a more compact implementation than the pixel 30 of FIG. 2 by allocating the storage area under the first transfer gate 85.

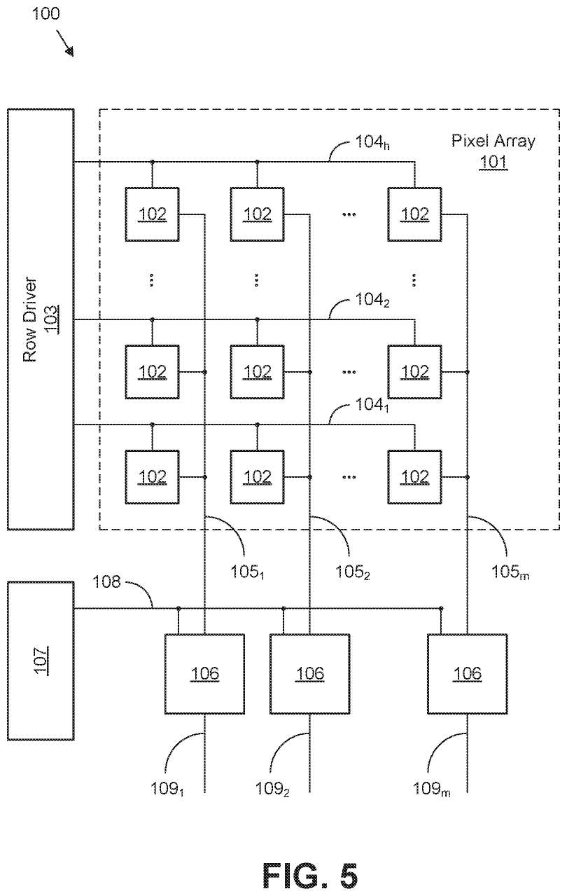

FIG. 5 shows an image sensor 100 in accordance with an embodiment. The image sensor 100 includes a pixel array 101 with pixels 102, a row driver 103, a column readout circuit 106 for each column of pixels 102 in the pixel array 122, and a column circuit timing controller 107 that controls the analog-to-digital conversion (ADC) by the column readout circuits 106. The pixel array 101 includes pixels 102 that are arranged in rows and columns. In some embodiments, each pixel 102 has a structure of the pixel 10 of FIG. 1. In some embodiments, each pixel 102 has a structure of the pixel 30 of FIG. 2. In some embodiments, each pixel 102 has a structure of the pixel 50 of FIG. 3. In some embodiments, each pixel 102 has a structure of the pixel 80 of FIG. 4. With reference to FIG. 5, the row driver 103 supplies control signals to the pixels 102 in the pixel array 101 to control operations of the pixels 102.

Pixels 102 that are in a same row of the pixel array 101 share common row control signals from the row driver 103. For example, pixels 102 in a first row of the pixel array 101 share common row control lines 104i for receiving control signals from the row driver 103. Similarly, pixels 102 in a second row of the pixel array 101 share common row control lines 1042 for receiving control signals from the row driver 103, and pixels 102 in an h^{th} row of the pixel array 101 share common row control lines 104ₕ for receiving control signals from the row driver 103. Pixels 102 that are in a same column of the pixel array 101 share a common column readout line to provide output. For example, pixels 102 in a first column of the pixel array 101 share a column readout line 105₁, pixels 102 in a second column of the pixel array 101 share a column readout line 105₂, and pixels 102 in an m⁺ column of the pixel array 101 share a column readout line 105ₘ. In various embodiments, the row driver 103 controls the pixels 102 to provide output row by row.

Each column readout circuit 106 is connected to receive analog signals from a corresponding column readout line, and is configured to provide digital output on a corresponding output line. For example, the column readout circuit 106 for the first column is connected to the column readout line 105₁ for receiving input, and is connected to an output line 109₁ for providing output. Similarly, the column readout circuit 106 for the second column is connected to the column readout line 105₂ for receiving input, and is connected to an output line 109₂ for providing output, and the column readout circuit 106 for the m⁺ column is connected to the column readout line 105ₘ for receiving input, and is connected to an output line 109ₘ for providing output. The column circuit timing controller 107 is configured to provide control signals to the plurality of column readout circuits 106 over one or more control lines 108. Each column readout circuit 106 is configured to digitize a difference between a pixel output signal and the signal of a reset potential from the pixel to provide a digital output representing the charge collected by the pixel during the corresponding exposure.

Referring to FIGS. 1 and 5, in a case where the pixel 10 is used for the pixels 102 in the pixel array 101, the row control lines such as the row control lines 104₁, provide the anti-blooming control signal AB, the first transfer control signal TX, the storage gate signal SG, the second transfer control signal TX2, the reset control signal RST, and the row select signal ROW. Also, in such a case, the corresponding column readout line such as the column readout line 105₁ for a pixel 102 in the pixel array 101 serves as the readout line 24 for the pixel 10.

Referring to FIGS. 2 and 5, in a case where the pixel 30 is used for the pixels 102 in the pixel array 101, the row control lines such as the row control lines 104₁, provide the anti-blooming control signal AB, the first transfer control signal TX, the storage gate signal SG, the second transfer control signal TX2, the reset control signal RST, and the row select signal ROW. Also, in such a case, the corresponding column readout line such as the column readout line 105₁ for a pixel 102 in the pixel array 101 serves as the readout line 44 for the pixel 30.

Referring to FIGS. 3 and 5, in a case where the pixel 50 is used for the pixels 102 in the pixel array 101, the row control lines such as the row control lines 104i, provide the anti-blooming control signal AB, the first transfer control signal TX, the storage gate signal SG, the second transfer control signal TX2, the reset control signal RST, and the row select signal ROW. Also, in such a case, the corresponding column readout line such as the column readout line 105₁ for a pixel 102 in the pixel array 101 serves as the readout line 64 for the pixel 50.

Referring to FIGS. 4 and 5, in a case where the pixel 80 is used for the pixels 102 in the pixel array 101, the row control lines such as the row control lines 104₁, provide the anti-blooming control signal AB, the first transfer control signal TX, the second transfer control signal TX2, the reset control signal RST, and the row select signal ROW. Also, in such a case, the corresponding column readout line such as the column readout line 105₁ for a pixel 102 in the pixel array 101 serves as the readout line 94 for the pixel 80.

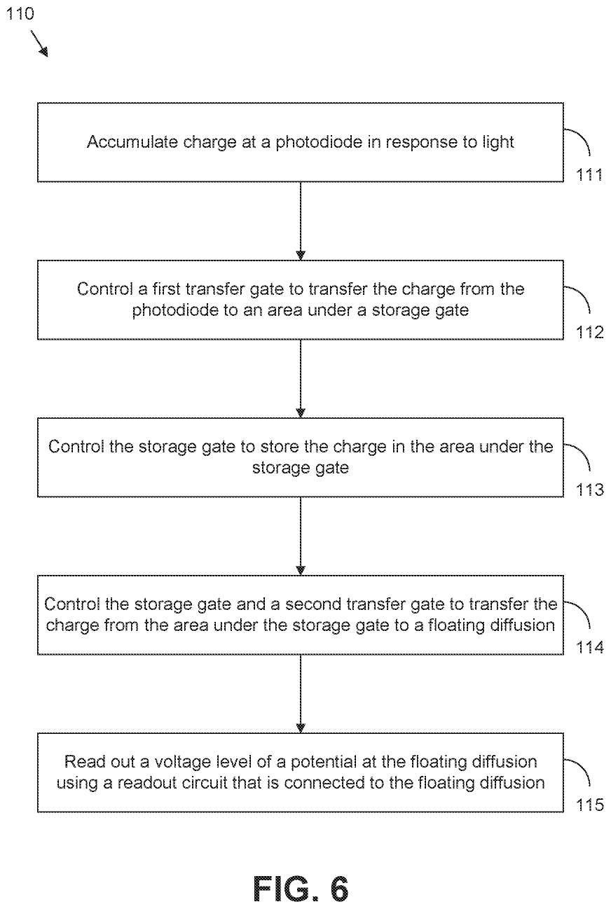

FIG. 6 is a flowchart of a method 110 in accordance with an embodiment that is performable in an image sensor such as, for example, the image sensor 100 of FIG. 5 that includes a pixel such as, for example, the pixel 10 of FIG. 1, the pixel 30 of FIG. 2, or the pixel 50 of FIG. 3. Referring to FIGS. 3 and 6, in step 111 charge is accumulated at a photodiode in response to light. For example, charge is accumulated at the photodiode 52 in response to light. In step 112, a first transfer gate is controlled to transfer charge from the photodiode to an area under a storage gate. For example, the first transfer gate 55 is controlled to transfer charge from the photodiode 52 to the area 59 under the storage gate 56. In step 113, the storage gate is controlled to store the charge in the area under the storage gate. For example, the storage gate 59 is controlled to store the charge in the area 59 under the storage gate 56.

In step 114, the storage gate and a second transfer gate are controlled to transfer the charge from the area under the storage gate to a floating diffusion. For example, the storage gate 56 and the second transfer gate 57 are controlled to transfer the charge from the area 59 under the storage gate 56 to the floating diffusion 58. In step 115, a voltage level of a potential at the floating diffusion is read out using a readout circuit that is connected to the floating diffusion. For example, a voltage level of a potential at the floating diffusion 58 is read out using the readout circuit 61 that includes the source follower transistor 62 that is connected to the floating diffusion 58. In various embodiments, the first transfer gate is controlled by a first transfer control signal, the storage gate is controlled by a storage gate signal, and the second transfer gate is controlled by a second transfer control signal. For example, the first transfer gate 55 is controlled by the first transfer control signal TX, the storage gate 56 is controlled by the storage gate signal SG, and the second transfer gate 57 is controlled by the second transfer control signal TX2.

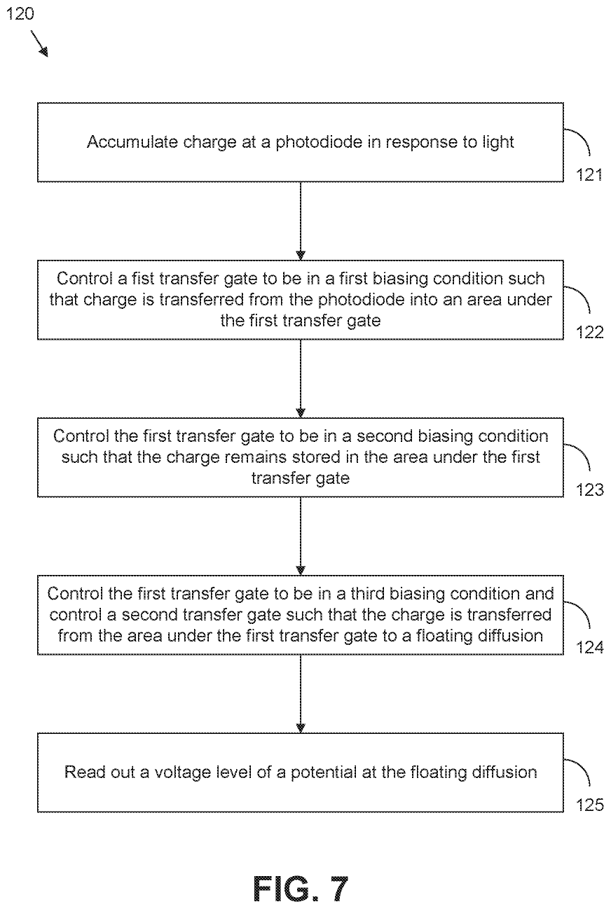

FIG. 7 is a flowchart of a method 120 in accordance with an embodiment that is performable in an image sensor such as, for example, the image sensor 100 of FIG. 5 that includes a pixel such as, for example, the pixel 80 of FIG. 4. Referring to FIGS. 4 and 7, in step 121 charge is accumulated at a photodiode in response to light. For example, charge is accumulated at the photodiode 82 in response to light. In step 122, a first transfer gate is controlled to be in a first biasing condition such that charge is transferred from the photodiode into an area under the first transfer gate. For example, the first transfer gate 85 is controlled to be in the first biasing condition such that charge is transferred from the photodiode 82 into the area 89 under the first transfer gate 85. In step 123, the first transfer gate is controlled to be in a second biasing condition such that the charge remains stored in the area under the first transfer gate. For example, the first transfer gate 85 is controlled to be in the second biasing condition such that the charge remains stored in the area 89 under the first transfer gate 85.

In step 124, the first transfer gate is controlled to be in a third biasing condition and a second transfer gate is controlled such that the charge is transferred from the area under the first transfer gate to a floating diffusion. For example, the first transfer gate 85 is controlled to be in the third biasing condition and the second transfer gate 87 is controlled such that the charge is transferred from the area 89 under the first transfer gate 85 to the floating diffusion 88. In step 125, a voltage level of a potential at the floating diffusion is read out. For example, a voltage level of a potential at the floating diffusion 88 is read out. In various embodiments, the first transfer gate 85 is controlled to be in the second biasing condition by applying a voltage of a particular voltage level to the first transfer gate 85, and the first transfer gate 85 is controlled to be in the first biasing condition by applying a voltage at a level higher than the particular voltage level to the first transfer gate 85, and the first transfer gate 85 is controlled to be in the third biasing condition by applying a voltage at a level lower than the particular voltage level to the first transfer gate 85.

The embodiments disclosed herein are to be considered in all respects as illustrative, and not restrictive of the invention. The present invention is in no way limited to the embodiments described above. Various modifications and changes may be made to the embodiments without departing from the spirit and scope of the invention. For example, although some of the above embodiments have been described with reference to the formation of n type implants in a p type substrate, various other embodiments may equally use p type implants in an n type substrate. Various modifications and changes that come within the meaning and range of equivalency of the claims are intended to be within the scope of the invention.

What is claimed is:

1. A pixel, comprising:
a storage gate controllable to store charge in an area under the storage gate and to transfer the charge from the area under the storage gate;
a first transfer gate controllable to transfer the charge from a photodiode to the area under the storage gate;
a floating diffusion that is connected to a readout circuit to allow the readout circuit to read out a voltage level of a potential at the floating diffusion; and
a second transfer gate controllable to transfer the charge from the area under the storage gate to the floating diffusion.

2. The pixel of claim 1, wherein the storage gate is connected to receive a storage gate signal that controls the storage gate.

3. The pixel of claim 1, wherein the storage gate is located between the first transfer gate and the second transfer gate.

4. The pixel of claim 1, wherein the storage gate, the first transfer gate, and the second transfer gate are polysilicon gates.

5. The pixel of claim 1,
wherein the readout circuit comprises a source follower transistor; and
wherein the floating diffusion is directly connected to a gate of the source follower transistor.

6. The pixel of claim 1, further comprising a reset transistor that is connected between a reset voltage source and the floating diffusion and that has a gate connected to receive a reset control signal.

7. The pixel of claim 1, further comprising:
a substrate under the storage gate, the first transfer gate, and the second transfer gate;
a first implant in the substrate located between an area under the first transfer gate and the area under the storage gate; and
a second implant in the substrate located between the area under the storage gate and an area under the second transfer gate.

8. The pixel of claim 7, wherein the first implant and the second implant each comprise arsenic.

9. The pixel of claim 7, further comprising:
a first barrier implant in the substrate under a portion of the storage gate; and
a second barrier implant in the substrate under a portion of the second transfer gate.

10. The pixel of claim 9, wherein the first barrier implant and the second barrier implant each comprise boron.

11. An image sensor, comprising:
a pixel array comprising a plurality of pixels, at least one pixel of the plurality of pixels comprising:
a photodiode;
a storage gate controllable to store charge in an area under the storage gate and to transfer the charge from the area under the storage gate;
a first transfer gate controllable to transfer the charge from the photodiode to the area under the storage gate;
a floating diffusion that is connected to a readout circuit to allow the readout circuit to read out a voltage level of a potential at the floating diffusion; and
a second transfer gate controllable to transfer the charge from the area under the storage gate to the floating diffusion.

12. A method, comprising:
controlling a first transfer gate to transfer charge from a photodiode to an area under a storage gate;
controlling the storage gate to store the charge in the area under the storage gate;
controlling the storage gate and a second transfer gate to transfer the charge from the area under the storage gate to a floating diffusion; and
reading out a voltage level of a potential at the floating diffusion using a readout circuit that is connected to the floating diffusion.

13. The method of claim 12,
wherein the first transfer gate is controlled by a first transfer control signal;
wherein the storage gate is controlled by a storage gate signal; and
wherein the second transfer gate is controlled by a second transfer control signal.

14. A pixel, comprising:
a floating diffusion that is connected to a readout circuit to allow the readout circuit to read out a voltage level of a potential at the floating diffusion;
a first transfer gate that is controllable among a first biasing condition in which charge is transferable from a photodiode to an area under the first transfer gate, a second biasing condition in which the charge is storable in the area under the first transfer gate, and a third biasing condition in which the charge is transferable out of the area under the first transfer gate; and
a second transfer gate controllable to transfer the charge from the area under the first transfer gate to the floating diffusion.

15. The pixel of claim 14, further comprising:
a substrate under the first transfer gate and the second transfer gate; and
an implant in the substrate located between the area under the first transfer gate and an area under the second transfer gate.

16. The pixel of claim 15, wherein the implant comprises arsenic.

17. The pixel of claim 14, further comprising:
a substrate under the first transfer gate;
a photodiode comprising an implant in the substrate;
wherein a portion of the implant extends under a portion of the first transfer gate.

18. A method, comprising:
controlling a first transfer gate to be in a first biasing condition such that charge is transferred from a photodiode into an area under the first transfer gate;
controlling the first transfer gate to be in a second biasing condition such that the charge remains stored in the area under the first transfer gate; and
controlling the first transfer gate to be in a third biasing condition and controlling a second transfer gate such that the charge is transferred from the area under the first transfer gate to a floating diffusion.

19. The method of claim 18, further comprising:
reading out a voltage level of a potential at the floating diffusion.

20. The method of claim 18,
wherein the first transfer gate is controlled to be in the second biasing condition by applying a voltage of a particular voltage level to the first transfer gate;
wherein the first transfer gate is controlled to be in the first biasing condition by applying a voltage at a level higher than the particular voltage level to the first transfer gate; and
wherein the first transfer gate is controlled to be in the third biasing condition by applying a voltage at a level lower than the particular voltage level to the first transfer gate.
